(19) United States
(12) Patent Application Publication
(10) Pub. No.: US 2006/0118942 A1
(43) Pub. Date: Jun. 8, 2006

(54) Optoelectric module with handle-based delatching mechanism

(76) Inventor: William Lee Schmidt, Los Gatos, CA (US)

Correspondence Address: ROBERT A. PARSONS, 4000 N. CENTRAL AVENUE, SUITE 1220, PHOENIX, AZ, 85012, US

(21) Appl. No.: 10/624,692

(22) Filed: Jul. 22, 2003

Related U.S. Application Data
(60) Provisional application No. 60/401,576, filed on Aug. 6, 2002.

(51) Int. Cl. H01L 23/053; G02B 6/36

(52) U.S. Cl. 257/700; 385/88

(57) ABSTRACT

A package comprising an elongated housing and a handle-based delatching mechanism fixedly attached to the elongated housing wherein the handle-based delatching mechanism includes a slide fixedly attached to a handle, the handle being fixedly attached to the elongated housing at a pivot point for movement between a closed position and an open position wherein the elongated housing includes a track for receiving and guiding the slide when the handle is moved between the closed position and the open position and wherein a portion of the slide is positioned in abutting engagement with spring fingers when the handle is in the open position and the elongated housing is positioned within a rack.

### CROSS-REFERENCE TO RELATED APPLICATIONS

This application claims benefit to U.S. provisional application Ser. No. 60/401,576, filed Aug. 6, 2002.

### FIELD OF THE INVENTION

This invention relates to transceiver packages and more particularly to latching and delatching apparatus for the transceiver packages.

### BACKGROUND OF THE INVENTION

At the present time, optical-to-electrical and electrical-to-optical (hereinafter “optoelectric”) packages, containing a pair of optoelectric modules, are contained in one common or standard package. The modules are generally used in pairs for two-way communication. Multiple optoelectric packages are used in a common mounting rack to provide multiple communication channels. The optoelectric packages are positioned in the rack in, for example, rows and columns and, to save space the optoelectric packages are positioned as close together as possible.

Each optoelectric package is constructed to be inserted into an opening or cage in the rack. Once the optoelectric package is inserted completely into the cage, the optoelectric package is captured by means of a latch spring inside the cage that is positioned to engage a locking tab on the optoelectric package. To release the optoelectric package and remove it from the cage, the latch spring must be disengaged from the locking tab, after which the optoelectric package can be withdrawn from the cage.

The problems that arise result chiefly from the closeness, size and shape of the optoelectric packages. The optoelectric packages are generally oblong in shape with a multi-pin electrical plug or socket at the rear or inner end which mates with a multi-pin electrical socket or plug in the cage. The optoelectric package must nest snugly in the cage since any relative movement would eventually cause failures. However, because of the firm fit, withdrawal of the optoelectric package from the cage requires some effort. Because of the closeness of the multiple optoelectric packages in the rack, access to each optoelectric package is limited. Also, the latch spring must be disengaged from the locking tab as the optoelectric package is withdrawn.

In one prior art solution a simple linear actuator is provided. The linear actuator is pushed forward to raise the latch spring in the cage to release it from the locking tab. For this design, the linear actuator is entirely located under the optoelectric package and, therefore, is difficult to access. That is, one must push the linear actuator forward with one hand to raise the latch spring and then grip and pull the optoelectric package. This combined pushing and pulling action, along with the need to firmly grip whatever portion of the optoelectric package is available for gripping, is very inconvenient.

Another solution used in the prior art uses a locking tab on the end of a lever spring. This, solution requires a different rack and cage arrangement. Instead of moving the latch spring (as described above) in the cage, the locking tab is displaced to clear the latch and unlock the optoelectric package. Springs can be unreliable. For example, the spring can be bent or deformed by repeated use and will no longer effectively lock the optoelectric package into the cage.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 is a front-top isometric view of an optoelectric cage;

FIG. 2 is a front-top isometric view of the optoelectric module used in the prior art;

FIG. 3 is a side-top isometric view of an optoelectric module in accordance with the present invention, with a handle in a locked orientation;

FIG. 4 is a side-top isometric view of an optoelectric module in accordance with the present invention, with the handle in an unlocked orientation;

FIG. 5 is an isometric view of the handle in accordance with the present invention; and

FIG. 6 is an isometric view of a slide in accordance with the present invention.

### DETAILED DESCRIPTION OF THE DRAWINGS

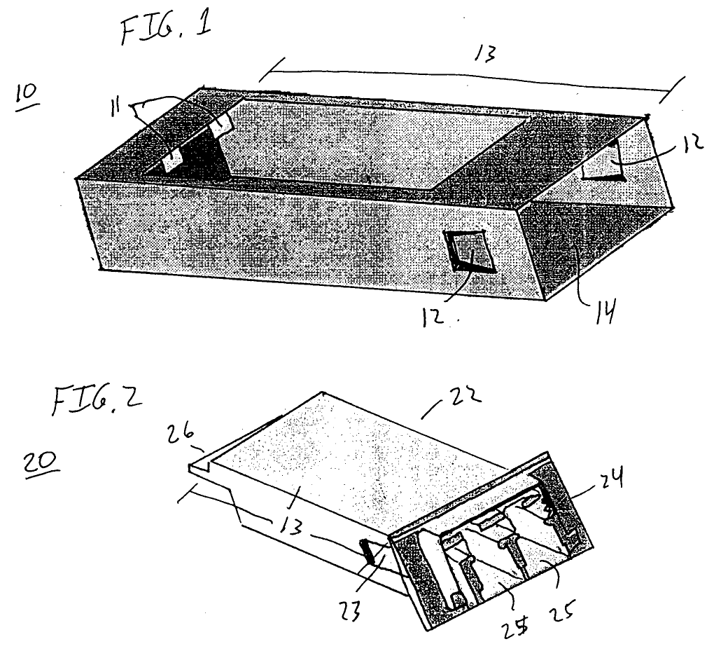

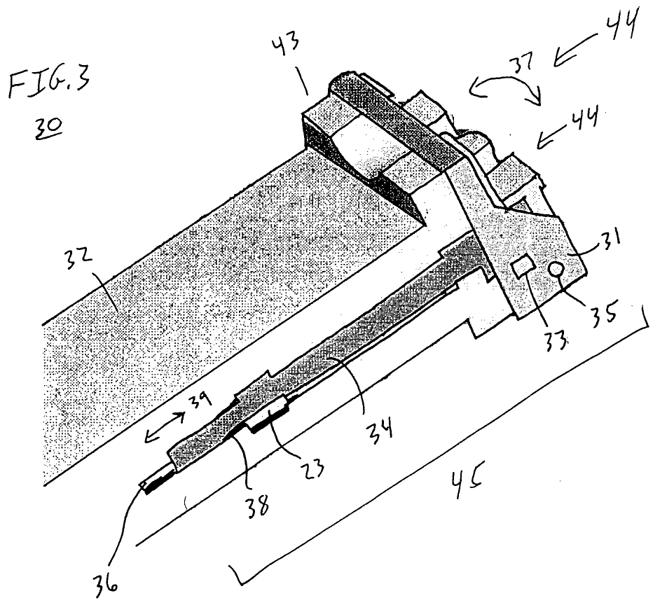

Turning now to FIG. 1, an optoelectric cage 10 is illustrated. Optoelectric cage 10 is designed to hold an optoelectric module (See FIG. 2) which slides into an opening 14. The optoelectronic module can be slid rearward a distance 13 as determined by tabs 11. Spring fingers 12 are positioned on cage 10 to hold the optoelectronic module firmly in place, as will be discussed presently.

Turn now to FIG. 2 which illustrates a prior art optoelectric module 20. Module 20 includes an elongated housing 22 with a rear end 26 which makes contact with tabs 11 when module 20 is inserted into cage 10. Housing 22 includes a header 24, which is typically formed of a single piece and may be manufactured by some convenient means, such as molding or the like. Header 24 is mated with the elongated portions of housing 22 and includes a pair of openings 25 designed to receive an optical-to-electrical module (not shown) in one side and an electrical-to-optical module (not shown) in the other side.

Module 20 further includes detents 23 which engage spring fingers 12 so that module 20 is held firmly within cage 10 to minimize vibrations and other such movement which can affect the performance and alignment of module 20. As such, removing module 20 from cage 10 poses problems because spring fingers 12 are typically difficult to disengage from detents 23 due to space limitations.

Turning now to FIG. 3, an optoelectric module 30 in accordance with the present invention is illustrated. Optoelectric module 30 includes an elongated housing 32 with a length 13 such that module 30 can be placed within cage 10. In this embodiment, elongated housing 32 is formed of metal and includes detents 46 positioned to frictionally engage an inner surface of a cage in a mounting rack (not shown), such as spring fingers 12 (See FIG. 1). Detents 46 ensure a positive contact between optoelectric module 30 and cage 10 to prevent relative movement, once optoelectric module 30 is properly nested in cage 10, and ensures that cage 10 and optoelectric module 30 are electrically connected. Further, elongated housing 32 includes tracks 36 whose function will be discussed separately.

Elongated housing 32 includes a header 43, which in this embodiment is formed of a single piece and may be manufactured by some convenient means, such as molding or the like. Header 43 is mated with the elongated portions of housing 32 and includes a pair of openings 44 designed to receive an optical-to-electrical module (not shown) in one side and an electrical-to-optical module (not shown) in the other side. Optoelectric package 30 may have either the plug or socket of a multipin electrical connector at the rear end (not shown), which plug or socket is positioned to mate with a socket or plug in the mounting rack when the optoelectric package is properly nested in the cage of the mounting rack. In this embodiment, it is anticipated that each module includes a printed circuit board with multiple contacts formed on a rearwardly extending surface. Each of the modules may electrically connect to the multipin electrical connector at the rear end (not shown) of elongated housing 32 when the modules are properly inserted into openings 44.

In the preferred embodiment, a handle-based delatching mechanism 45 is attached to elongated housing 32 and header 43. Handle-based delatching mechanism 45 includes a handle 31 and a slide 34. In the preferred embodiment, handle 31 is formed as a separate assembly and attached to header 43 during a final assembly. In the preferred embodiment, handle 31 includes a ramp 38 which is used to disengage spring fingers 12 (See FIG. 1) as will be discussed separately. In the preferred embodiment, ramp 38 is formed by bending handle 34 as shown. However, it will be understood that handle 31 can include other means to disengage spring fingers 12.

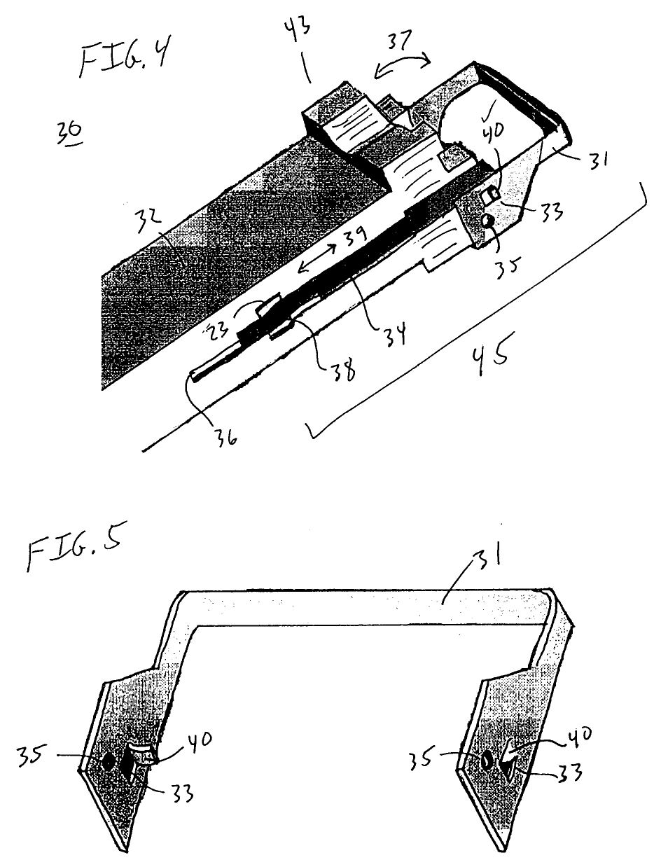

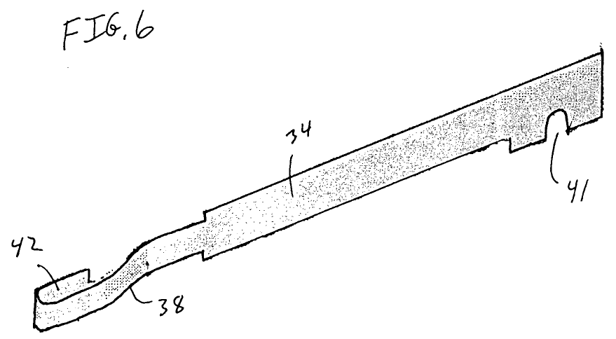

Handle 31 is attached to header 43 using pins attached to header 43 (not shown) which can mate with openings 35. Handle 31 is pivotally mounted in header 43 for movement between a closed position, illustrated in FIG. 3, and an open position, illustrated in FIG. 4, as handle 31 is moved in a direction 37. In this preferred embodiment, handle 31 is formed from metal, which is sturdy and easy to form. However, it will be understood that handle 31 can be formed from other suitable materials, such as plastic or the like.

In the preferred embodiment, handle 31 is attached to slides 34 through tabs 40 (See FIG. 6) formed from openings 33 wherein tabs 40 interlock with slots 41 (See FIG. 6). However, it will be understood that handle 31 can be attached to slides 34 through other means well known to those skilled in the art, such as a screw or the like. Slides 34 are positioned within tracks 36 of elongated housing 32 which allows slides 34 to move in a direction 39.

As lever arm 31 moves from the closed position to the open position along direction 37, slide 34 moves along tracks 36 in direction 39. Ramp 38 engages spring fingers 12 (not shown) to disengage optoelectric module 30 from cage 10. Hooks 42 slide forward to interlock with elongated housing 32. Handle 31 can then be used to easily withdraw module 30 from opening 14.

While a handle-based delatching mechanism is illustrated in conjunction with a specific optoelectric module 30, it will be understood that it may be used with other optoelectric packages and may be incorporated as an integral portion or added during assembly. Also, while a specific handle 31 and slide 34 are illustrated and described, it will be understood that other embodiments may be devised which essentially perform the same functions.

Thus, handle-based delatching mechanism 45 improves the delatching feature because handle 31 is in an unobstructed position and accessibility is greatly increased. Also, handle 31 and slide 34 are formed of sturdy and reliable material which greatly increases the life and reliability of the assembly. Handle 31 not only allows the unlatching of optoelectric package 30 but provides a convenient sturdy grip for the removal of optoelectric package 30 from cage 10 so that packing density is no longer a problem.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A package comprising:
an elongated housing; and
a handle-based delatching mechanism fixedly attached to the elongated housing wherein the handle-based delatching mechanism includes a slide fixedly attached to a handle.

2. A package as claimed in claim 1 wherein the handle is fixedly attached to the elongated housing at a pivot point for movement between a closed position and an open position.

3. A package as claimed in claim 2 wherein the elongated housing includes a track for receiving and guiding the slide when the handle is moved between the closed position and the open position.

4. A package as claimed in claim 3 wherein a portion of the slide is positioned in abutting engagement with spring fingers when the handle is in the open position and the elongated housing is positioned within a rack.

5. A package as claimed in claim 3 wherein the slide is capable of being moved along the track wherein a ramp positioned on the slide engages spring fingers in a rack.

6. A package as claimed in claim 1 wherein an end of the slide mechanically engages the elongated housing when the handle is moved from the closed position to the open position.

7. A package as claimed in claim 3 wherein a portion of the slide disengages spring fingers when the elongated housing is positioned within the rack such that spring fingers fixedly hold the elongated housing in the rack by engaging detents positioned on the elongated housing.

8. A package as claimed in claim 1 wherein the elongated housing can be disengaged from a rack when the slide is mechanically engaged against spring fingers included in the rack as the handle is moved from the closed position to the open position.

9. An optoelectric package comprising:
an elongated housing with a side and an opposed side;
a first track positioned on the side of the elongated housing and a second track positioned on the opposed side of the elongated housing;
a header mated with the elongated portions of the housing wherein the header includes a pair of openings designed to receive at least one optoelectronic module; and
a handle-based delatching mechanism fixedly attached to the header, wherein the handle-based delatching mechanism includes
a handle fixedly attached to a side and an opposed side of the header; and
a first slide and a second slide fixedly attached to the handle, the first slide being positioned within the first track and the second slide being positioned within the second track.

10. A package as claimed in claim 9 wherein the header includes at least one molded piece.

11. A package as claimed in claim 9 wherein the first slide moves along the first track and the second slide moves along the second track when the handle is moved between a closed position and an open position.

12. A package as claimed in claim 9 wherein a portion of at least one of the first and second slides is in abutting engagement with spring fingers when the handle is in the open position and the elongated housing is positioned within a rack.

13. A package as claimed in claim 9 wherein the first and second slides engage spring fingers in a rack when the handle is moved to the open position.

14. A package as claimed in claim 9 wherein at least one of the handle, slide, and elongated housing includes at least one of a metal and a plastic.

15. A package as claimed in claim 9 wherein the elongated housing can be disengaged from a rack when the first and second slides are cammed against spring fingers included in the rack.

16. A package as claimed in claim 9 wherein the first and second slides include a hook which slidingly engages the elongated housing when the handle is moved from the closed position to the open position.

17. A package as claimed in claim 9 wherein a portion of the first and second slides disengages spring fingers when the elongated housing is positioned within a rack such that spring fingers fixedly hold the elongated housing in the rack by engaging detents positioned on the elongated housing.

18. A method of engaging or disengaging a package from a rack, the method comprising the steps of:
providing an elongated housing;
fixedly attaching a handle-based delatching mechanism to the elongated housing wherein the handle-based delatching mechanism includes a slide fixedly attached to a handle; and
moving the handle between a closed position and an open position wherein a portion of the slide engages or disengages spring fingers positioned on the rack.

19. A method as claimed in claim 18 wherein the step of fixedly attaching the handle-based delatching mechanism to the elongated housing includes a step of fixedly attaching the handle to the elongated housing at a pivot point for movement of the handle between the closed position and the open position.

20. A method as claimed in claim 18 wherein the step of providing the elongated housing includes a step of providing the elongated housing with a track for receiving and guiding the slide when the handle is moved between the closed position and the open position.

21. A method as claimed in claim 18 wherein the step of moving the handle between the closed position and the open position includes a step of moving the handle from the closed position to the open position such that the slide mechanically engages the elongated housing and the spring finger is disengaged from a detent on the elongated housing.

22. A method as claimed in claim 18 wherein the step of moving the handle between the closed position and the open position includes a step of moving the handle from the open position to the closed position such that the slide mechanically disengages the elongated housing and the spring finger is engaged into a detent on the elongated housing.

23. A method as claimed in claim 18 wherein the step of moving the handle between the closed position and the open position includes a step of engaging the elongated housing mechanically with an end of the slide as the handle is moved from the closed position to the open position
